(19) United States
(12) Patent Application Publication
(10) Pub. No.: US 2009/0125726 A1
(43) Pub. Date: May 14, 2009

(54) Method and Apparatus of Providing the Security and Error Correction Capability for Memory Storage Devices

(75) Inventors: Sree M. Iyer, San Jose, CA (US); Arunprasad Ramiya Mothilal, Santa Clara, CA (US); Santosh Kumar, Santa Clara, CA (US)

Correspondence Address: The TPL Group, 20400 Stevens Creek Blvd., Fifth Floor, Cupertino, CA, 95014, US

(73) Assignee: MCM PORTFOLIO LLC, Cupertino, CA (US)

(21) Appl. No.: 11/949,652

(22) Filed: Dec. 3, 2007

Related U.S. Application Data
(60) Provisional application No. 60/988,050, filed on Nov. 14, 2007.

(51) Int. Cl. G06F 12/14; G06F 12/06; G11C 29/52

(52) U.S. Cl. 713/189; 711/209; 714/763; 711/E12.092; 711/E12.078; 714/E11.034

(57) ABSTRACT

A method and apparatus of configuring the byte structure of a memory storage device, including a flash memory device, to enhance the security and error correction capability is described. In one embodiment, the method includes increasing the security of data stored in the storage device by encrypting data with a unique initialization vector and storing the initialization vector in the storage device. The method also includes using a unique initialization vector for encrypting data, to be stored in each datablock, each time data are encrypted. In one embodiment, the apparatus includes an AES controller that includes encryption and decryption modules to encrypt and decrypt data prior to writing data to or reading from the storage device. The apparatus also includes an encoder module and decoder circuits to encode and decode data prior to writing or reading from memory storage devices. The apparatus optionally includes a state machine that generates and provides the initialization vector and also activates different components of AES controller and ECC module depending on the operation of the device.

### RELATED PATENT APPLICATION

This application claims the benefit of U.S. Provisional Application No. 60/988,050 filed Nov. 14, 2007.

### COPYRIGHT NOTICE/PERMISSION

A portion of the disclosure of this patent document contains material which is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD OF THE INVENTION

The invention relates to securing data, and correcting errors in memory devices, especially flash memory devices in portable electronic equipment.

### BACKGROUND

As portable electronic devices become more popular, securing data is necessary. That is, these devices may contain personal and confidential information and they are easily lost or stolen. To protect data, users may employ encryption and decryption techniques. These techniques encrypt data prior to storing them and decrypt data after accessing them. A key enables secure data handling.

“Plaintext” is data before encryption, while “ciphertext” is data after encryption. Various encryption algorithms (known collectively as “ciphers”) protect sensitive information stored in various memory devices. These encryption methods may be divided into two categories, symmetric key algorithms and asymmetric key algorithms. A user of a symmetric key algorithm keeps an encryption key secret (“private key”).while a user of an asymmetric key algorithm employs two different keys. Of the two asymmetric keys, one enables any sender to encrypt data (“public key”) and the other key, only known to a receiver, allows decryption of data (“private key”).

A symmetric key algorithm can be further categorized into two types called block ciphers and stream ciphers. Block ciphering involves dividing data into various blocks and encrypting each block, while stream ciphering involves encrypting continuous streams of data. Block ciphering can be implemented using various ciphering techniques such as but not limited to Electronic Code Book mode (ECB), Cipher Block Chaining (CBC), Cipher Feedback (CFB), and Output Feedback (OFB). The ECB technique involves dividing data into blocks and encrypting each block with the same encryption key. However if identical plaintext blocks are encrypted using the ECB method, identical ciphertext blocks are generated making the encrypted data vulnerable to security attacks. The CBC method involves an initialization vector (IV) to encrypt (XOR) a first block. This generates a first ciphertext which in turn is used to encrypt the second block. Then the second ciphertext is used to encrypt the third block and so on to the end of the plaintext.

Cipher Feedback (CFB) is similar to Cipher Block Chaining (CBC), but instead of encrypting the XORed block, it starts by encrypting a seeded value, and then XORing the encrypted seeded value with the first block. The first block of cipher text generated is encrypted and XORed with the second block. This process is repeated until all data are encrypted. Output Feedback is similar to Cipher Feedback. OFB begins by encrypting the seed and XORing that value with the first block of clear text to obtain the first block of cipher text. The encrypted seed is then encrypted again, and then that value is used to XOR with the second block. This process is repeated until all the blocks are encrypted.

Data security may be enhanced by using a unique IV to encrypt each chain (n number of blocks can be called a chain). Initialization vector n bits long can provide 2ⁿ different IV values; however the odds of two IVs being the same would be square root of 2ⁿ. For example, four bytes of data would provide 2³² (4,294,967,296) different values, the odds of two IVs being the same in the scenario is 2¹⁶ (65,536). If each unique IV value is used to encrypt a segment (assuming 512 bytes of memory), the IV would repeat itself at 512* 65,536 bytes (32 MB). As current data storage technology, such as flash memory, may hold gigabytes of data, the chance of an IV repeating itself is high. Prior art systems address this problem by increasing the size of the IV, thus reducing the probability of repetition. Prior art systems stored the IV used to encrypt data in an external memory device, fetching the IV as needed to decrypt data. This technique has performance limitations. The existing encryption techniques are not efficient because of, among other things, loss of performance, reduced error correction capability, and reduction of available storage space. This invention has been made to address these failings in the prior art. This invention provides a mechanism to encrypt and decrypt data stored in memory devices, especially flash memory devices, without compromising error correction capability.

As described in U.S. Pat. No. 7,137,011, the functions of encryption and decryption may involve a host computer and a daughter memory card. The host often is a personal computer. The daughter card, in many cases incorporating non-volatile flash memory, is removeably connected to a mother card on the host computer. This allows the daughter card to be moved among different mother cards, thus allowing data to be transferred between different host computers. Because of the possibility of theft or loss of the daughter card, data may need to be encrypted. To encrypt or decrypt data, it is necessary to store keys and algorithms. In the '011 patent, storage of a decryption algorithm is on the daughter card. Not described in the '011 patent is any detail on how encryption and decryption is performed.

U.S. Pat. No. 6,618,789 describes how an encryption algorithm can be stored on the daughter memory card. A data processing unit and the memory card each have an encrypting function allowing data processing unit and memory card to be mutually authenticated. The memory card has processing circuitry to allow data encryption and authentication.

The '789 patent further describes how to employ the encryption function according to Data Encryption Standard (DES): “The DES is a block encrypting system in which text is block-segmented and each block segment is encrypted. With DES, input data of 64 bits is encrypted with a key of 64 bits (in reality, a key of 56 bits and a parity of 8 bits) and encrypted data of 64 bits is output. The DES has four use modes, one of which is a Cipher Block Chaining mode. The [Cipher Block Chaining] mode is a feedback type mode in which text of 64 bits and the preceding encrypted data (of 64 bits) are XORed and the result is input to the DES unit. In the initial state, since there is no encrypted data, an initialization vector is used. In addition, as data are being exchanged between the set and the memory card, random numbers may be generated and added to the data.”

A drawback of the prior art described in the '789 patent is that it is limited to DES; the invention in this patent application discloses the use of Advanced Encryption Standard (AES) in place of DES. One difference between AES and DES is that AES supports a larger range of block and key sizes; AES has a fixed block size of 128 bits and a key size of 128, 192 or 256 bits. Another difference is that DES has been compromised by brute force computer attacks while AES is resistant. It is not a simple matter of substituting AES for DES encryption in an application; implementing AES in an architecture is beyond the ability of someone of ordinary skill in the art of implementing DES.

### SUMMARY OF THE INVENTION

A method and apparatus of configuring the byte structure of a memory device, including a flash memory device, to enhance the security and error correction capability is described. In one embodiment, the method includes increasing the security of data stored in the memory device by encrypting data by a unique initialization vector and storing the initialization vector in the memory device. The method also includes using a unique initialization vector for encrypting data, to be stored in each datablock, each time data are encrypted.

In one embodiment, the apparatus includes an AES controller that includes encryption and decryption modules to encrypt and decrypt data prior to writing data to or reading from a storage device. The apparatus also includes encoder module and decoder circuits to encode and decode data prior to writing or reading from memory devices. The apparatus optionally includes a state machine that generates, selects, or retrieves, and provides the initialization vector and also activates different components of AES controller and ECC module depending on the operation of the device.

For the purposes of this application, references to “storage device” and “flash memory” include memory devices in general including but not limited to, flash memory, RAM, non-volatile memory, hard drive, and equivalents including data transmitted over communications media. Likewise, references to RAM include equivalents such as but not limited to non-volatile memory.

The details of the present invention, both as to its structure and operation, and many of the attendant advantages of this invention, can best be understood in reference to the following detailed description, when taken in conjunction with the accompanying drawings, in which like reference numerals refer to like parts throughout the various views unless otherwise specified, and in which:

### BRIEF DESCRIPTION OF THE DRAWINGS

FIG. 1 is a block diagram of the present invention.

FIG. 2 illustrates in detail various components of the invention and interface between the various components.

FIG. 3a illustrates a configuration byte structure of flash memory device at datablock level.

FIG's 3b, 3c, and 3d illustrate alternative configuration byte structure of flash memory device at datablock level.

FIG. 4 illustrates the byte structure of an individual segment of flash memory device.

FIG. 5 illustrates the encryption process at a datablock level.

FIG. 6 illustrates the decryption process at a datablock level.

FIG's 7a, 7b, and 7c illustrate the operation of state machine during write process.

FIG's 8a, 8b, 8c, and 8d illustrate the operation of state machine during read process.

### DETAILED DESCRIPTION OF THE PREFERRED EMBODIMENTS

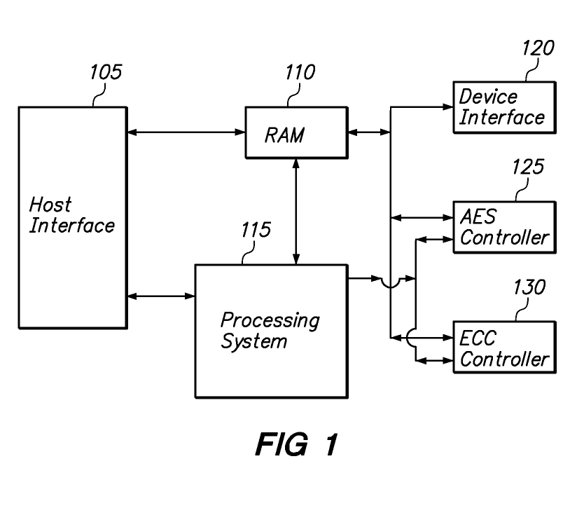

FIG. 1 shows the block diagram of the present invention, which includes a host interface 105, random access memory (RAM) module 110, processing system 115, device interface 120, advanced encryption standard (AES) controller 125, and error correction code (ECC) controller 130. The host interface 105 is couple to RAM module 110 and processing system 115. The RAM module 110 is further coupled to device interface 120, AES controller 125 and ECC controller 130. RAM module 110 transfers data between the host interface 105 and the device interface 120. Device interface 120 can be coupled to one or more storage devices such as but not limited to flash memory and hard drive to read data from and write data to the storage devices.

The AES controller 125 encrypts or decrypts data that is being the written to or read from a target storage device. ECC controller 130 encodes and decodes data prior to being written or read from target storage devices to detect and correct the errors. Processing system 115 is used to generate the control signals required to activate the AES controller 125 and ECC controller 130.

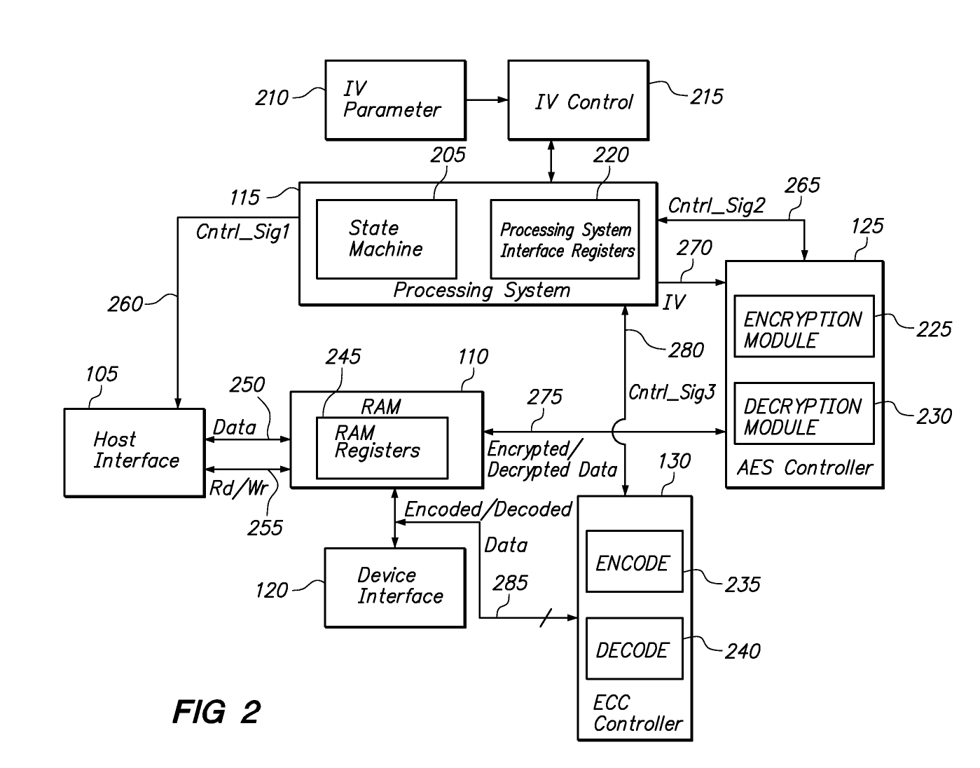

FIG. 2 illustrates in more detail different components of processing system 115, RAM module 110, AES controller 125, and ECC controller 130 and communication interface between the various components. Processing system 115 has a state machine 205 and processing system interface registers 220. The state machine 205 generates the control signals to enable RAM module 110, modules of AES controller 125, and ECC controller 130. In one embodiment, the present invention uses initialization vector (IV) to encrypt or decrypt data that is written to or read from the storage device. In one embodiment, the IV is generated from a random number 210 such that it provides a random number for the encryption process. IV control 215 is used to update the IV, if the encryption process for a new datablock is initiated (explained in further detail in FIG's 3, 4, 7, and 8). The IV control 215 updates the processing system interface registers 220 with a new IV on determining that data are being written to a new datablock. AES controller 125 has an encryption module 225 used to encrypt data being written to the target flash memory device and a decryption module 230 used to decrypt data being read from the target flash memory device. ECC controller 130 includes an encoder module 235 to encode the encrypted data, IV, and firmware status bits that are written to the flash memory device and a decoder module 240 to decode data read from the flash memory device to detect and correct errors in data. The RAM module 110 is updated by the host interface 105, AES controller 125, ECC controller 130 and device interface 120 during read and write operations.

Device Interface 120

In one embodiment, host controller 105 transfers data to RAM module 110 using data signal 250 and initiates a write cycle using the control signal 260. Host interface 105 notifies the state machine 205 utilizing the control signal cntrl_sig1 260 to notify that data are available in the RAM module 110. The state machine 205 activates the encryption module 225 to encrypt data stored in the RAM module 110 using the control signal cntrl_sig2 265 and provides the IV stored in the processing system interface registers 220 utilizing the IV signal 270. AES controller 125 stores data encrypted by the encryption module 225 in the RAM module 110 using data signal 275. State machine 205 activates the encoder module 235 of ECC controller 130 to encode the encrypted data, IV, and status/firmware bits by activating the control signal cntrl_sig3 280. Encoder module 235 encodes data and generates the parity bits and provides the parity using signal data/parity 285. State machine 205 commands the device interface 120 using control signal cntrl_sig4 245 to transfer data and parity to the target flash memory device.

In one embodiment, host controller 105 requests the device interface module 120 to read data from the target flash memory device using the control signal rd/wr 255. State machine 205 commands device interface module 120 using control signal cntrl_sig4 245 to read data from the flash memory device and write to the RAM module 110. RAM module 110 notifies state machine 205 that data are available to read using control signal 265. The state machine 205 on receiving data generates a control signal cntrl_sig3 280 to activate the decoder module 240 of ECC controller 130. Decoder module 240 decodes data to detect and correct errors in data stored in the flash memory device. If no errors are present in the decoded data, the state machine 205 activates the decryption module 230 of the AES controller 125 using the control signal cntrl_sig2 265. In case, where the decoder module 240 detects the errors that can be fixed, the decoder corrects the errors in data and the corrected data are provided to the decoder module 240. If the detected errors are not correctable, state machine 205 employs error measures such as but not limited to notifying the host interface 105 that data are corrupt. The decryption module 230 decrypts data and provides the decrypted data using data signal 275. The host interface 105 reads the decrypted data from the RAM module 110.

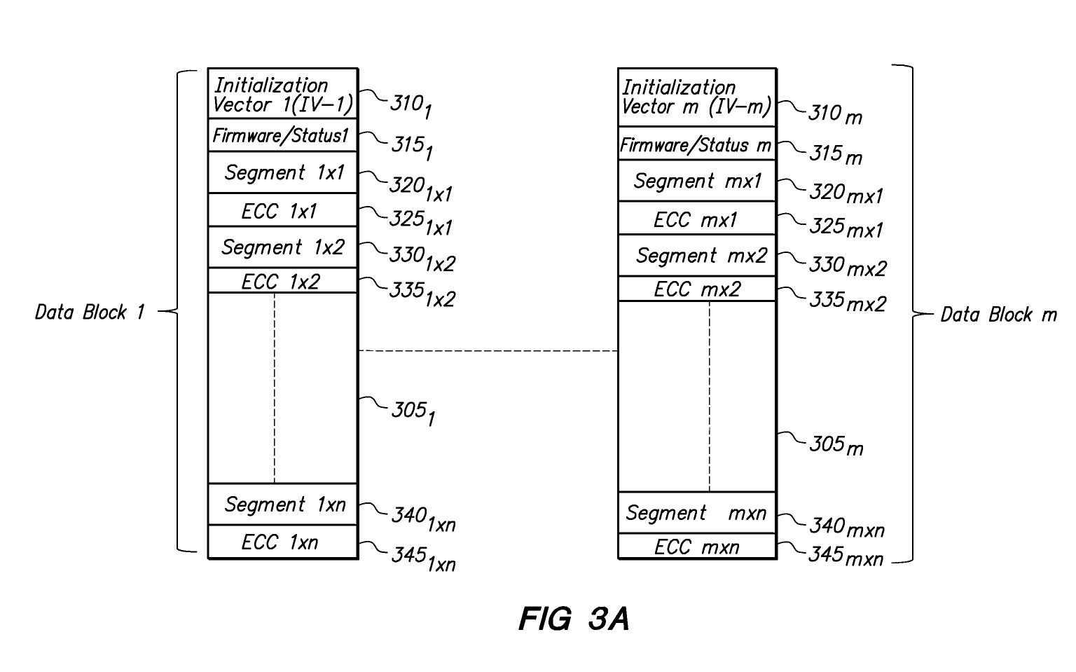

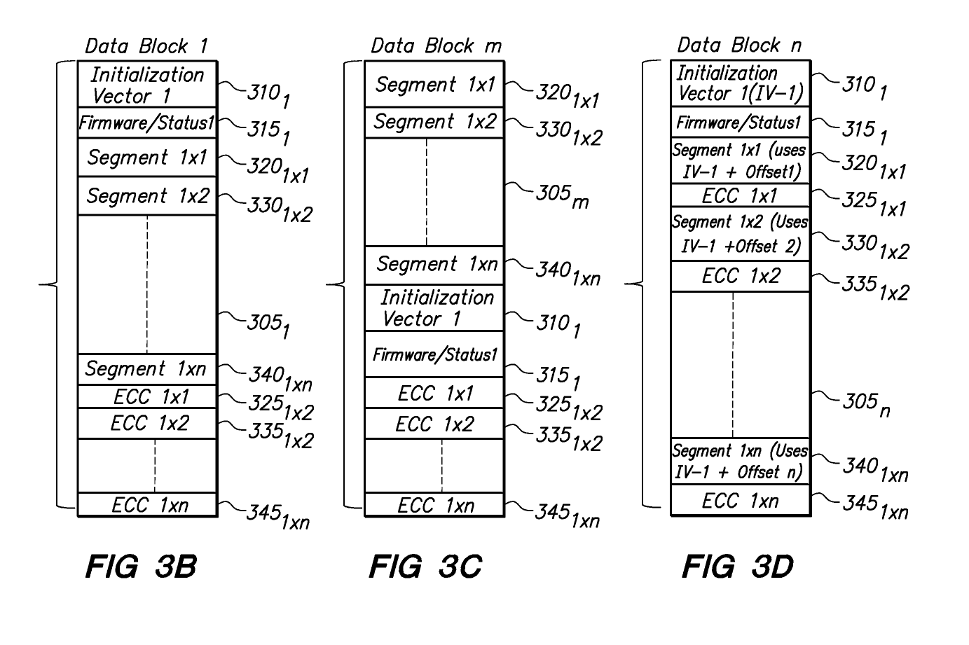

FIG. 3a illustrates flash memory device having m datablocks, datablock-1 to datablock-m 305₁-305ₘ. Datablocks datablock-1 to datablock-m 305₁-305ₘ are designed to store an IV, status/firmware bits, data and parity bits. Each datablock datablock-1 to datablock-m 305₁-305ₘ utilizes unique IV initialization vector-1 to initialization vector-m 310₁-310ₘ and firmware/status bits 315₁-315ₘ to encrypt data respectively. Each type of datablock, datablock 1, datablock m, and datablock n (305₁, 305ₘ, and 305ₙ), can be further divided into n segments (referred to as chain), such as segment 1x1, segment 1x2 to segment 1xn ((32O₁ₓ₁, 330₁ₓ₂ to 340₁ₓₙ), to store encrypted data and ECC blocks, ECC 1x1, ECC 1x2 to ECC 1xn ((325₁ₓ₁, 335₁ₓ₂ to 345₁ₓₙ)ₙ)) to store ECC parity bits. The present invention configures each datablock to store an efficient IV in a storage device without affecting the performance, and ability to detect or correct errors of data stored in the flash memory.

Table 1 illustrates how the present invention enhances the error correction capability of the flash memory by increasing the size of segments.

TABLE 1

| Extra bits | | Number of | | | Number of | Number of | Number of |
|---|---|---|---|---|---|---|---|
| per 512 | No of | bytes per | Number of | Number of | bytes for | Available | Used |
| bytes | Segments | Segment | IV Bytes | F/W Bytes | ECC parity | Bytes | Bytes |
| 128 | 8 | 512 bytes | 4 | 2 | 15 | 4224 | 4222 |
| 128 | 4 | 1024 bytes | 14 | 2 | 28 | 4224 | 4224 |

It may be assumed that 4K datablock bytes of flash memory has 128 bits of redundant data space available per 512 bytes of data. Based on the assumptions there would 128 bytes (128*8 bits) of redundant data space available. The 4K datablock of flash memory can be divided into eight segments of 512 bytes or four segments of 1024 bytes. In the scenario, where the datablock is divided into eight segments of 512 bytes, 128 bytes of redundant space available is used for 4 bytes for IV, 2 bytes for firmware/status bytes and 120 bytes (15 bytes for each segment) for storing parity bits. The fifteen bytes of ECC for each segment may be able to correct up to 8 bits of errors. Whereas, if 4K datablock of flash memory is divided into four segments of 1024 bytes, 128 bytes of redundant data available for the datablock is utilized for 14 bytes of IV, two bytes for firmware or status bytes and 28 bytes of ECC data for each segment. The 28 bytes of ECC data may be able to correct up to 16 bits errors in data stored in the flash memory. Thus by organizing the 4K datablocks into bigger segments, the present invention provides an efficient solution to enhance security and the error correction capability.

Table 2 illustrates the byte structure of the 4K datablocks of flash memory depending on the redundant data space available.

TABLE 2

| Extra bits | | F/W | | | | | | | | |
|---|---|---|---|---|---|---|---|---|---|---|
| per 512 | IV | Status | Segment1 | | | | | | | |
| bytes | (Bytes) | (Bytes) | (Bytes) | ECC1 | Segment2 | ECC2 | Segment3 | ECC3 | Segment4 | ECC4 |
| 128 | 14 | 2 | 1024 | 28 | 1024 | 28 | 1024 | 28 | 1024 | 28 |
| 218 | 16 | 2 | 1024 | 49 | 1024 | 49 | 1024 | 49 | 1024 | 49 |

For example, a 4K datablock having a redundant space of 128 bits for every 512 bytes can be configured to include 14 bytes of IV and 2 bytes of firmware status and four segments, each segment having 1024 bytes of storage space and 4 ECC blocks of 28 bytes. On the other hand, a 4K datablock having redundant space of 218 bits for every 512 bytes can be configured to include 16 bytes of IV and 2 byte of firmware status and four segments, each segment having 1024 bytes of storage space and 4 ECC blocks having 49 bytes. The redundant data space available thus increases the error correction capability of data stored in segments.

FIG's 3b and 3c depict how datablocks datablock-1 to datablock-m 305₁-305ₘ can be alternately organized to achieve similar results as configuration shown in FIG. 3a. Instead of arranging segments and ECC blocks alternately as shown in FIG. 3a, segments may be grouped sequentially with ECC blocks also grouped sequentially. FIG. 3b illustrates how segments segment1x1, segment1x2 to segment 1xn of datablock1 and segment mx1, segment are organized after each other instead of having ECC blocks, ECC1x1, ECC 1x2 to ECC 1xn alternated with each segment.

In FIG. 3c, the initialization vector initialization vector-1 310₁ and firmware status bits firmware/status 1 315₁ are stored between segments segment 1x1, segment1x2 to segment 1xn (320 1x1, 330 1x2-340 1xn) and ECC blocks, ECC1x1, ECC1x2 to ECC1xn ((325 1x1, 325 1x2-325 1xn)-(325 1x1, 325 1x2-325 1xn)).

FIG. 3d illustrates another embodiment of the invention in which each segment segment-1, segment-2 to segment-n (320_{1x1, 330}₁ₓ₂₋340₁ₓₙ) uses the initialization vector, initialization vector-1 310₁, with different offsets to encrypt data. Offset can be introduced by adding one or more bits to the initialization vector-1 310₁.

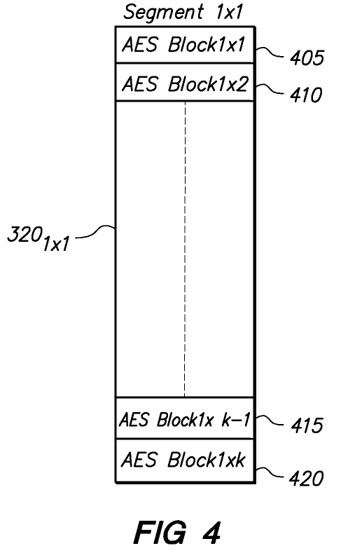

FIG. 4 illustrates segment-1 320₁ₓ₁ of datablock-1 305₁ having k AES blocks, AES block-1x1 405, AES block 1x2 410, to AES block 1xk-1 415, and AES block 1xk 420. Segment 1x1 (320₁ₓ₁) is divided into multiple AES blocks of different sizes. The encryption and decryption of data are performed at AES block level. The number of AES blocks needed for a segment is based on the size of the datablock and the AES encryption method used. For example, 1024 byte datablock utilizing a 128 bit AES encryption method includes 64 16 byte segments.

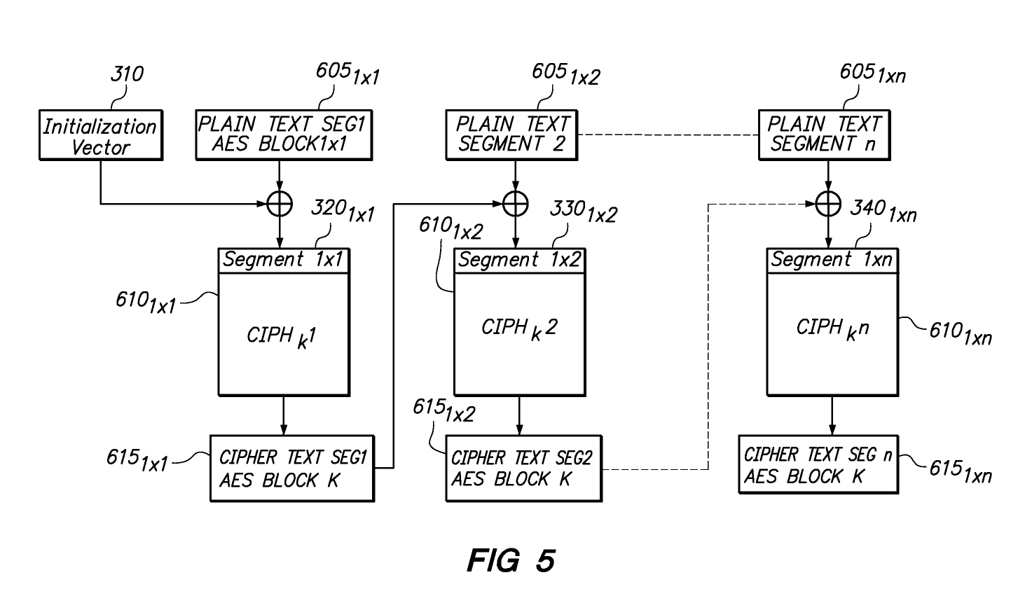

FIG. 5 illustrates the method used to encrypt data that will be stored in datablock1 305₁ having a chain of segments: segment-1x1, segment1x2 to segment1xn 320₁ₓ₁, 330₁ₓ₂, and 340₁ₓₙ. State machine 205 enables encryption module 225 of AES controller 125 to encrypt data on detecting the write request. Encryption module 225 begins the encryption process CIPHₖ 1 610₁ₓ₁ by accepting input of AES block size PLAIN TEXT SEG1 AES block1x1 605_{1X1} and encrypts data by XORing with initialization vector 310₁ and generating the output CIPHER TEXT SEG1 AES blockk 615₁ₓ₁. The encryption process CIPHₖ 1, CIPHₖ 2 to CIPHₖ n (610₁ₓ₁, 610₁ₓ₁, and 610₁ₓ₁) is carried out at data size of AES block size. The encryption process CIPHₖ 2-CIPHₖ n (610₁ₓ₁₋610₁ₓₙ) is repeated for the chain of segments segment 1x2-segment 1xn (330₁ₓ₂-340₁ₓₙ) by accepting further inputs PLAIN TEXT SEG2 AES block1x1 and PLAIN TEXT SEGn AES block1xn (605₁ₓ₂-605₁ₓₙ) and encrypting data using the preceding AES block cipher data and thus generating outputs CIPHER TEXT SEG2 AES block k and CIPHER TEXT SEGn AES block k (615₁ₓ₂₋615₁ₓₙ).

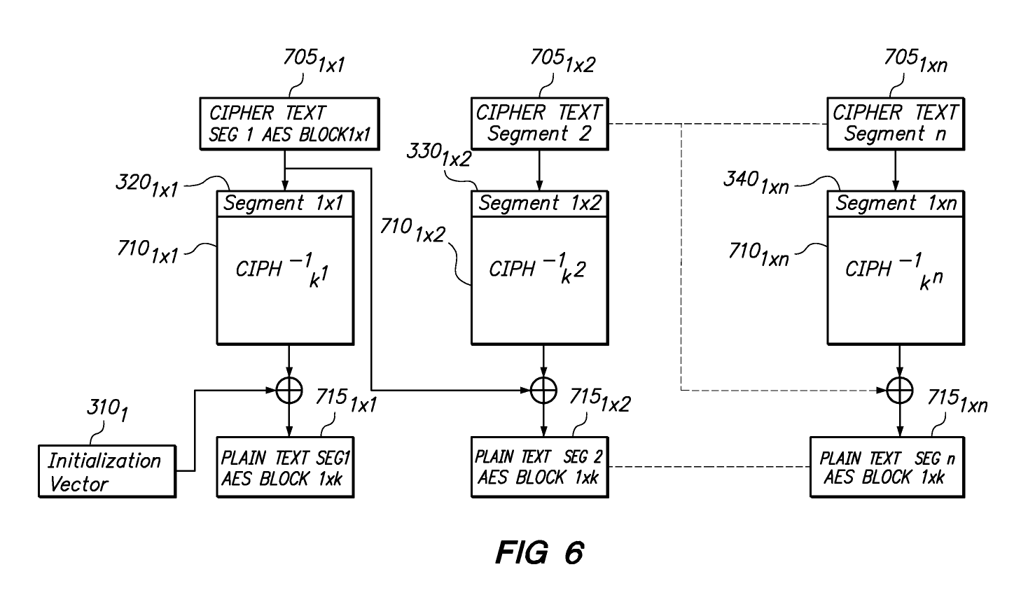

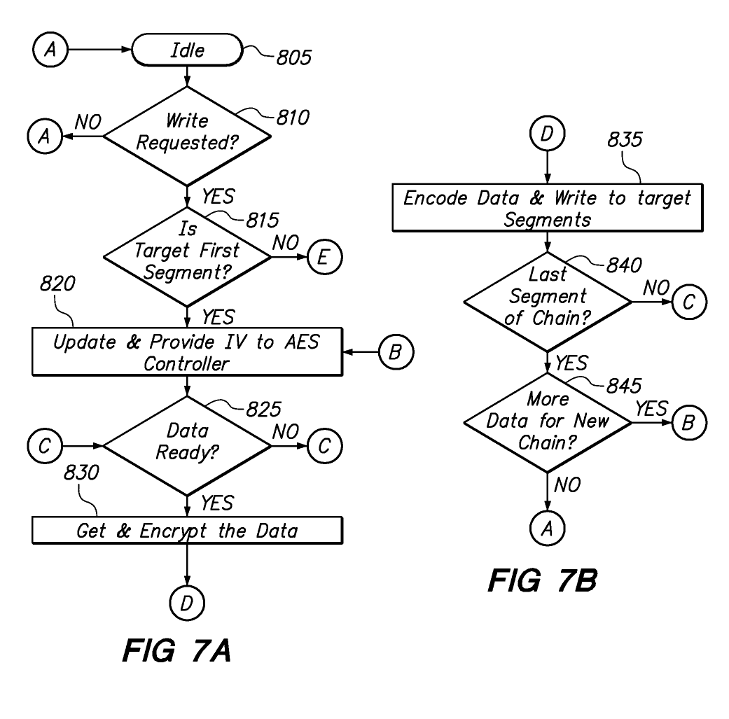

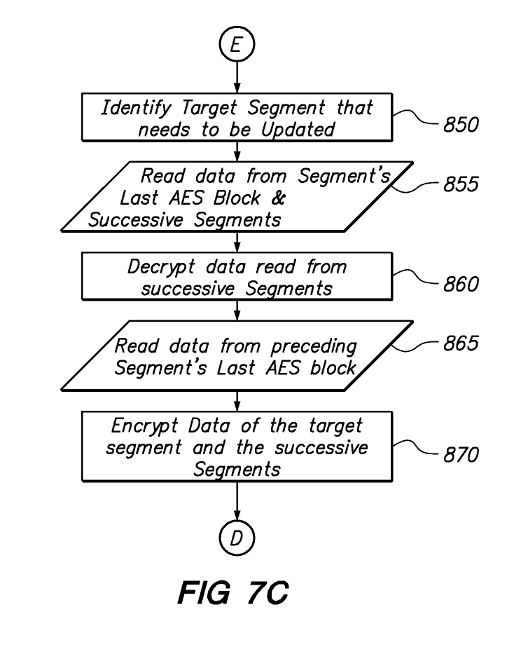

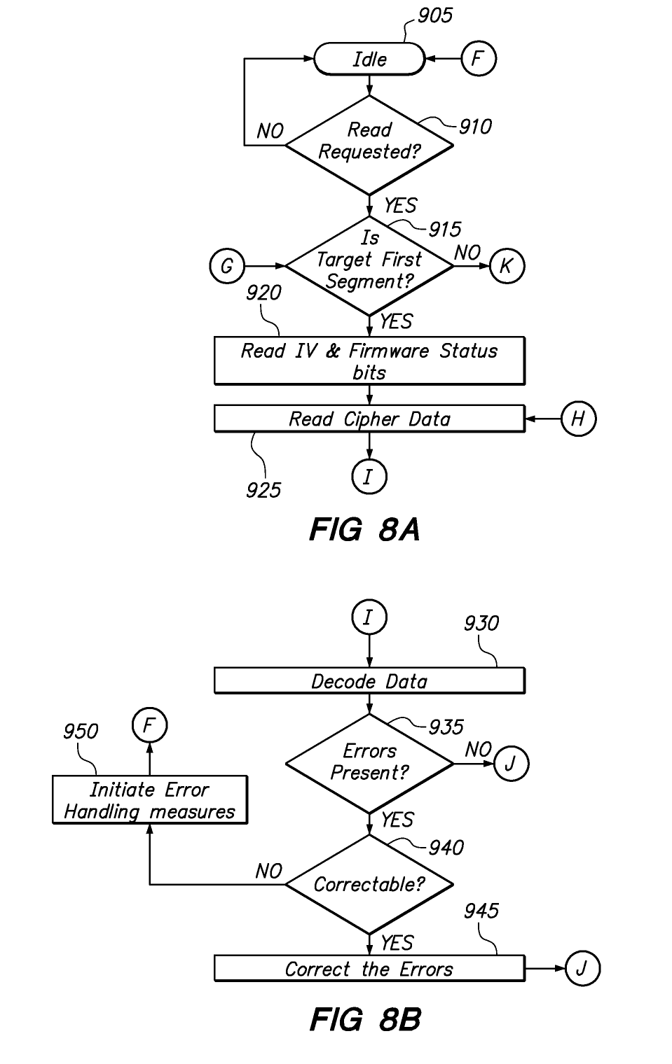

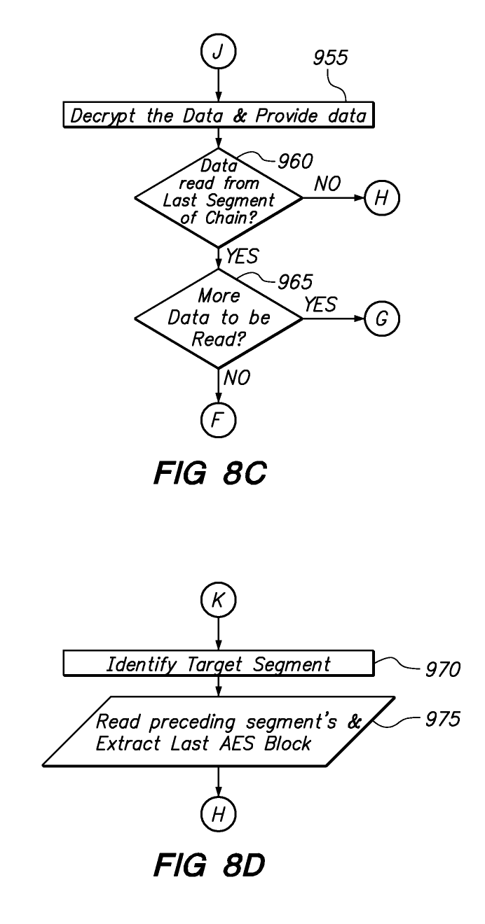

FIG. 6 illustrates the method used to decrypt data that is stored in datablock1 305₁ having chain of segments segment-1x1, segment1x2 to segment1xn 320₁ₓ₁, 330₁ₓ₂, and 340₁ₓₙ. State machine 205 enables decryption module 230 of AES controller 125 to decrypt data on detecting the read request. Decryption module 230 begins the decryption process CIPH⁻¹ₖ 1 710₁ₓ₁ by accepting input of AES block size CIPHER TEXT SEG1 AES block1x1 705₁ₓ₁ and decrypting data by XORing with initialization vector 310₁ and generating the output PLAIN TEXT SEG1 AES block 1xk 715₁ₓ₁. The decryption process CIPH⁻¹ₖ 1, CIPH⁻¹ₖ 2 to CIPH⁻¹ₖ n (710₁ₓ₁, 710₁ₓ₁, and 710₁ₓ₁) is carried out at data size of AES block size. The decryption process CIPH⁻¹ₖ 2 to CIPH⁻¹ₖ n (710₁ₓ₁₋710₁ₓₙ) is repeated for the chain of segmenets segment 1x2-segment 1xn (330₁ₓ₂-340₁ₓₙ) by accepting further inputs CIPHER TEXT SEG2 AES block1x2 and CIPHER TEXT SEGn AES block1xn (705₁ₓ₂-705₁ₓₙ) and decrypting data using the preceding AES block cipher data and thus generating outputs PLAIN TEXT SEG2 AES block 1xk and PLAIN TEXT SEGn AES block 1xk (715₁ₓ₂₋715₁ₓₙ). Even though FIG's 5, and 6 depict the encryption and decryption process using CBC encryption method, the encryption and decryption methods can be implemented by using other cipher algorithms such as but not limited to CFB and OFB.

FIG's 7a, 7b, and 7c illustrate the operation of the state machine 205 on detecting write command from the host interface 105. State machine 205 may initially operate in an idle state (step 805). The state machine 205 verifies if a write cycle is initiated by the host interface 105 on predetermined intervals and if the write cycle is not initiated it returns to idle state (step 81 0). (Alternately, the state machine 205 may wait for an interrupt signal from the host interface.) If the write cycle is initiated by the host interface 105, the state machine 205 verifies if target location is first segment of a datablock (step 815). If the target location is the first segment, state machine 205 updates the IV and provides the IV to the encryption module 225 of the AES controller (step 820). State machine 205 checks if data are ready for the encryption module to read and encrypt (step 825). If data are ready, the encryption module 225 obtains data and encrypts data by performing the encryption method shown in FIG. 5 and FIG. 6 (step 830). Encoder module 235 of ECC controller 130 encodes data encrypted and writes the encoded data and parity bits to the target segments (step 835). State machine 205 verifies if data are written to last segment of the datablock to determine if all of the chain of segments of the datablock are written (step 840). If the datablock is written to the last segment of the datablock, the state machine 205 verifies if more data needs to be written to the new chain of segments of a new datablock. If more data needs to be written, then state machine 205 returns to step 820. If there is no further data are available to write to the chain of segments in the new datablock, the state machine returns to the idle state (step 845).

If the state machine 205 determines that the target location in the flash memory device is anything other than that the first segment, the state machine 205 determines the target segment that needs to be updated (step 850). Prior to writing to the target segments, the state machine reads data from segment and the successive segments (step 855). Data read from the successive segments are decrypted (step 860). Data are read from the preceding segment and data of last AES block of the preceding segment is extracted (step 865). Data of the preceding segment's last AES block is used to encrypt data that needs to be written to the target segment. Data of the successive segments are encrypted again by using the encrypted data of the last AES block of the updated target segment. Once data are encrypted, the state machine returns to step 835 to encode data (step 870).

FIG. 8a, FIG. 8b, FIG. 8c, and FIG. 8d illustrate the operation of the state machine 205 on detecting the read command from the host interface. State machine 205 may initially operate in an idle state (step 905). The state machine 205 verifies if a write cycle is initiated by the host interface 105 on predetermined intervals and if the write cycle is not initiated it returns to idle state (step 910). (Alternately, the state machine 205 may wait for an interrupt signal from the host interface.) On the other hand, if data needs to be read from the first segment of the datablock, the state machine 205 verifies if data needs to read from the first segment of a datablock (step 915). If data needs to be read from the first segment of a datablock, the state machine 205 reads IV and firmware status bits (step 920). State machine reads the cipher data from the storage device (step 925). Data read from the storage device is decoded by using the decoder module 240 of ECC controller 130 to detect the presence of errors (step 930). The state machine 205 determines if the errors are present (step 935). If errors are present, then it is determined if they are correctable (step 940), in which case they are corrected (step 945), and the process proceeds to step 955. If errors are not correctable, then the process initiates error handling measures (step 950).

If no errors are detected, the decryption module 230 of the AES controller decrypts data (step 955). State machine 205 verifies if data are read from the last segment of the chain of segments in the datablock (step 960). In case data are not read from the last segment of chain of segments of the datablock, the state machine returns to step 925. If data are read from the last segment of the chain of segments of the datablock, state machine 205 verifies if more data needs to be read from a different chain of segments of another datablock and if more data needs to be read, the state machine 205 returns to step 915 otherwise returns to idle state (step 965). If more data needs to be read from another datablock, it returns to idle state, otherwise state machine 205 returns to step 920 (step 970).

If data needs to be read from a segment other than the first segment, the state machine identifies the location of the target segment (step 975). State machine reads data of the preceding segment and extracts the preceding segment's last AES block and returns to step 925.

While the particular method and apparatus as herein shown and described in detail is fully capable of attaining the above-described objects of the invention, it is to be understood that it is the presently preferred embodiment of the present invention and is thus representative of the subject matter which is broadly contemplated by the present invention, that the scope of the present invention fully encompasses other embodiments which may become obvious to those skilled in the art, and that the scope of the present invention is accordingly to be limited by nothing other than the appended claims, in which reference to an element in the singular means “at least one”. All structural and functional equivalents to the elements of the above-described preferred embodiment that are known or later come to be known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims.

We claim:

1. A method comprising:
accessing a storage device configured into a datablock, the datablock comprising an ordered series of one or more segments, each segment comprising an ordered series of one or more blocks, and each block containing data,
generating, selecting, or retrieving a unique initialization vector, the vector associated with the datablock,
using the vector to encrypt data contained in a first block of a segment chosen as a first segment for the datablock,
encrypting in order blocks subsequent to the first block, starting in immediate succession to the first block, using data stored in an immediately preceding block of the first segment, and
proceeding to encrypt data in blocks in succession in immediately successive segments using data from the immediately preceding block, initially for each segment using data from a final block of the immediately preceding segment.

2. The method of claim 1 wherein the vector is stored in the datablock.

3. The method of claim 1 wherein the storage device is selected from the group comprising flash memory, RAM, ROM, non-volatile memory, hard drive, and communications media.

4. The method of claim 1 wherein the one or more blocks are AES blocks.

5. The method of claim 4 wherein the vector is stored in the datablock.

6. A method comprising:
retrieving encrypted data from a storage device configured into a datablock wherein the datablock comprises an ordered series of one or more segments, and wherein each segment comprises an ordered series of one or more blocks,
using a unique initialization vector, the vector associated with the datablock and wherein the vector was used previously to encrypt data in the datablock, to decrypt a first block for segment previously designated as a first segment when the data in the datablock was encrypted with the vector,
decrypting subsequent blocks in order in the first segment starting in immediate succession to the first block, using data stored in an immediately preceding block of the first segment, and
proceeding to decrypt data in blocks in immediately successive segments using data from the immediately preceding block, initially for each segment using data from a final block of the immediately preceding segment.

7. The method of claim 6 wherein the vector is stored in the datablock.

8. The method of claim 6 wherein the storage device is selected from the group comprising flash memory, RAM, non-volatile memory, hard drive, and communications media.

9. The method of claim 6 wherein the one or more blocks are AES blocks.

10. The method of claim 6 wherein the vector is stored in the datablock and the one or more blocks are AES blocks.

11. A method of writing data to a datablock contained in a storage device wherein the datablock comprises an ordered series of segments, each segment comprising an ordered series of blocks, comprising the steps of:
writing data to a first block of a segment chosen as a first segment,
writing data to subsequent blocks in order in the first segment, wherein data written to each subsequent block corresponds with data in an immediate prior block, and
writing data to each block in order in succeeding segments in order using data associated with corresponding data to the immediately preceding block, initially for each segment using data from a final block of the immediately preceding segment.

12. The method of 11 wherein the steps of writing data comprises data that is encrypted.

13. The method of claim 11 further comprising:
writing an initialization vector, associated with the datablock, to the datablock.

14. The method of claim 11 wherein the storage device is selected from the group comprising flash memory, RAM, ROM, non-volatile memory, hard drive, and communications media.

15. The method of claim 11 wherein one or more of the series of blocks are AES blocks.

16. The method of claim 11 further comprising:
writing a plurality of parity bits, associated with the datablock, to the datablock for data error correction.

17. The method of claim 11 further comprising:
writing an initialization vector, associated with the datablock, in the datablock,
wherein the steps of writing data comprises data that is encrypted.
writing a plurality of parity bits, associated with the datablock, to the datablock for data error correction, and wherein
one or more of the series of blocks are AES blocks.

18. A memory comprising:
a storage device configured into one or more datablocks, each datablock comprising an ordered series of one or more segments, each segment comprising an ordered series of one or more blocks, and each block containing data; wherein the blocks, segments, and datablocks form a CBC; wherein the blocks are AES blocks; and wherein initialization vectors, corresponding one on one with each datablock, are stored, one per datablock, in each corresponding datablock.

19. The memory of 18 further comprising a plurality of parity bits, associated with each datablock, stored in an associated each datablock.

20. A memory comprising:
a storage device configured into one or more datablocks, each datablock comprising an ordered series of one or more segments, each segment comprising an ordered series of one or more blocks, and each block containing data; wherein the blocks, segments, and datablocks form a CBC; wherein the blocks are AES blocks; and wherein initialization vectors, corresponding one on one with each segment, are stored, one per segment, in each corresponding segment.

21. The memory of 20 further comprising a plurality of parity bits, associated with each datablock, stored in an associated each datablock.

22. A method comprising:
configuring the byte structure of a storage device into datablocks, segments and blocks wherein each datablock comprises one or more segments, and each segment comprises one or more blocks,
generating, selecting, or retrieving unique initialization vectors associated with each datablock to encrypt and decrypt data by introducing an offset where one or more bits of each initialization vector are changed, and
encrypting data by generating ciphertext of a first block of a segment of each datablock using one of the unique initialization vectors created, wherein encrypted data of successive blocks of each segment are encrypted generating ciphertext by using prior ciphertext generated from preceding blocks.

23. The method of claim 22, wherein the method of decrypting data comprises:
a. choosing an initialization vector previously associated with the first block of a segment of a datablock,
b. using the initialization vector to decrypt the first block into a first plaintext,
c. using ciphertext of the first block to decrypt a successive block into a successive plaintext,
d. using ciphertext of prior blocks to decrypt into plaintext associated successive blocks of successive segments, and
repeating steps a. to d. for each datablock in turn.

24. The method of claim 23 wherein the memory device is selected from the group comprising flash memory, RAM, non-volatile memory, hard drive, and communications media.

25. The method of claim 23 wherein the one or more blocks are AES blocks.

26. The method of claim 22 wherein the successive blocks of each segment are an ordered set, wherein the preceding blocks are an ordered set, wherein each successive block corresponds to one and only one of the preceding blocks, and wherein ciphertext of each successive block is generated from the corresponding ciphertext of the proceding block.

27. The method of claim 26 wherein the memory device is selected from the group comprising flash memory, RAM, non-volatile memory, hard drive, and communications media.

28. The method of claim 26 wherein the one or more blocks are AES blocks.

29. A datablock comprising:
a set of segments, each segment comprising a series of chained sequential blocks, associated one on one with prior blocks, wherein a first block in the chain, using an initialization vector, is encrypted into ciphertext and each subsequent block in the chain contains ciphertext generated from one of the each prior blocks in the chain.

30. The datablock of claim 29 wherein the blocks are AES blocks.

31. A datablock comprising:
a set of segments, each segment comprising a series of chained sequential blocks, associated one on one with prior blocks, wherein a first block in the chain, associated with ciphertext and using an initialization vector, is decrypted into plaintext and each subsequent block in the chain contains plaintext generated from ciphertext associated with one of prior blocks in the chain.

32. The datablock of claim 31 wherein the blocks are AES blocks.

33. A linked list of blocks wherein a first block in the list, using an initialization vector, is encrypted into ciphertext and each succeeding block in the list is encrypted into ciphertext using prior ciphertext of an immediate prior block in the linked list.

34. The blocks of claim 33 wherein the blocks are AES blocks.

35. A linked list of blocks in a segment wherein a first block in the list, associated with ciphertext and using an initialization vector contained in the segment, is decrypted into plaintext and each succeeding block in the list, associated with ciphertext, is decrypted into plaintext using prior ciphertext associated with an immediate prior block in the linked list.

36. The blocks of claim 35 wherein the blocks are AES blocks.

37. A segment, containing a linked list of blocks, wherein a first block in the list, using an initialization vector contained in the segment, is encrypted into ciphertext and each succeeding block in the list is encrypted into ciphertext using prior ciphertext of an immediate prior block in the linked list.

38. The blocks of claim 37 wherein the blocks are AES blocks.

39. A linked list of segments, forming a CBC chain, and
a linked list of unique initialization vectors corresponding one on one with the segments, wherein each succeeding vector in the list is formed by one or more offset bits of the prior vector, and wherein
each segment in order of the list contains a corresponding vector in order of the list.

40. The segments of claim 39 wherein each segment comprises a linked list of blocks wherein a first block in the list, using the vector contained in the segment, is encrypted into ciphertext and each succeeding block in the list is encrypted into ciphertext using prior ciphertext of an immediate prior block in the linked list.

41. The blocks of claim 39 wherein the blocks are AES blocks.

42. The blocks of 40 wherein the blocks are AES blocks.

43. An apparatus comprising:
a host device or interface,
one or more memories,
an AES controller having an encryption module to encrypt data,
an IV control module to generate, select, or retrieve an IV,
means for providing the IV to the AES controller,
an ECC controller having an encoding module, wherein:
the host provides data to a memory of the one or more memories,
the AES controller retrieves the data from the memory, encrypts the data using the vector, and writes the encrypted data and vector to the memory or another memory of the one or more memories, and
the ECC controller retrieves the encrypted data and IV from the memory, or the another memory, encodes the encrypted data and IV, generating parity bits, and writes the encoded data, encoded IV and parity bits in CBC format to the memory, another memory, or yet another memory of the one or more memories.

44. The apparatus of claim 43 wherein the means for providing the initialization vector to the AES controller is a state machine.

45. The apparatus of claim 43 wherein any or all of the one or more memories are selected from the group comprising flash memory, RAM, non-volatile memory, hard drive, and communications media.

46. The apparatus of claim 45 wherein the one or more memories each comprise a datablock wherein the IV, corresponding to the datablock, is written to the datablock.

47. The apparatus of claim 45 wherein the one or more memories comprises a segment wherein the IV, corresponding to the segment, is written to the segment.

48. An apparatus comprising:
a host device or interface,
one or more memories comprising a memory, another memory, or yet another memory wherein at least one of the memories contains data in CBC format,
an AES controller having an decryption module to decrypt data,
an ECC controller having an decoding module to decode data, wherein
the ECC controller retrieves parity bits, encoded encrypted data, and encoded encrypted IV from a memory, containing data in CBC format, uses the parity bits to check for and correct data errors, decodes the encrypted data and encrypted IV, and writes decoded encrypted data and decoded encrypted IV to the memory, another memory, or yet another memory of the one or more memories,
the AES controller retrieves decoded encrypted data and decoded encrypted IV from the memory, another memory, or yet another memory in which the ECC controller wrote the decoded encrypted data and decoded encrypted IV,
the AES controller decrypts the decoded IV, using the IV to decrypt the decoded encrypted data, and
the AES controller writes the decrypted data to the memory, another memory, or yet another memory.

49. The apparatus of claim 48 wherein any or all of the one or more memories is selected from the group comprising flash memory, RAM, non-volatile memory, hard drive, and communications media.

50. The apparatus of claim 48 wherein the one or more memories each comprise a datablock wherein the IV, corresponding to the datablock, is written to the datablock.

51. The apparatus of claim 48 wherein the one or more memories each comprise a segment wherein the IV, corresponding to the segment, is written to the segment.
